(19) United States
(12) Patent Application Publication
(10) Pub. No.: US 2023/0310253 A1
(43) Pub. Date: Oct. 5, 2023

(54) A PRODUCT CONTROLLED WITH WATERPROOF PIEZO CRYSTALS

(71) Applicant: ZAHi TECH GLOBAL ARGE SANAYi TiCARET LIMITED SiRKETi, Nilüfer/Bursa (TR)

(72) Inventor: Ömür Bakir, Küçükçekmece/Istanbul (TR)

(73) Assignee: ZAHi TECH GLOBAL ARGE SANAYi TiCARET LIMITED SiRKETi, Nilüfer/Bursa (TR)

(21) Appl. No.: 18/023,354

(22) PCT Filed: Sep. 18, 2020
(86) PCT No.: PCT/TR2020/050859

§ 371 Date: Feb. 25, 2023

(30) Foreign Application Priority Data
Sep. 3, 2020 (TR) 2020/13943

(51) Int. Cl. A61H 3/06; G08G 1/005; E01C 15/00; H10N 30/30; H10N 30/88

(52) U.S. Cl. CPC A61H 3/066; G08G 1/005; E01C 15/00; H10N 30/302; H10N 30/883; A61H 2003/063; A61H 2201/5074

(57) ABSTRACT

The invention relates to a product controlled with waterproof piezo crystals developed to control, through piezo crystals, the signaling system triggered before, during and after the crossing by pedestrians at signaled traffic intersections, wherein the product is highly durable and long-lasting, and facilitates use of signaled intersections by visually or hearing impaired and other pedestrians, and activates the signaling system, without the need to press any button, by detecting the pedestrians who stepped and applied pressure thereupon, thereby eliminating the risk of disease transmission.

### TECHNICAL FIELD

The invention relates to a product controlled with waterproof piezo crystals developed to control, through piezo crystals, the signaling system triggered before, during and after the crossing by pedestrians at signaled traffic intersections, wherein the product is highly durable and long-lasting, and facilitates use of signaled intersections by visually or hearing impaired and other pedestrians, and activates the signaling system, without the need to press any button, by detecting the pedestrians who stepped and applied pressure thereupon, thereby eliminating the risk of disease transmission.

### BACKGROUND ART

Piezoelectric property is the ability of some materials (especially crystals and certain crystals such as bone) to change electric field or electric potential in response to mechanical pressure applied thereto. This effect is directly related to the change in polarization density within such material. If the material is not short-circuited, the stress applied produces a voltage therewithin. The word ‘piezo’ is derived from Greek and means “to squeeze or compress, to apply pressure”. Piezoelectric materials are reversible, in other words, materials exhibiting “direct piezoelectric effect” (generation of electric potential when stress is applied) also exhibit converse piezoelectric effect (generation of stress-strain as a result of the applied electric field). For example, lead zirconate titanate crystals can change their shape up to 0.1% of their original size. This effect has useful applications such as “production and detection of sound”, “generation of high voltages”, “electronic frequency generation”, “microbalance”, and “ultra-fine focusing of optical assemblies”. Furthermore, it is the basis of a number of scientific techniques (scanning probe microscopes such as STM, AFM, MTA, SNOM etc.) as a result of atomic resolution and also, has its use in more mundane applications such as acting as the ignition source for lighters and barbeques. “Pyroelectric effect”, which is the property of materials to generate an electric potential in response to a temperature change, was studied by Cark Linnaeus and Franz Aepinus in the mid-18th century. Based on these studies, “Rene Just Hauy” and “Antoine Cesar Becquerel” suggested that there was a relationship between mechanical stress and electrical charge, however, experiments by both proved inconclusive. The direct piezoelectric effect was first demonstrated in 1880 by the brothers Pierre and Jacques Curie. By combining their knowledge of pyroelectricity with their understanding of the underlying crystal structures that gave rise to pyroelectricity to predict crystal behavior, they demonstrated the effect using crystals of tourmaline, quartz, topaz, cane sugar, and Rochelle salt (sodium potassium tartrate tetrahydrate). However, Curie brothers did not consider converse piezoelectric effect. The converse effect was mathematically deduced from the fundamental thermodynamic principles by Gabriel Lippmann. Thereupon, by confirming the presence of the converse effect, the Curie brothers proceeded to obtain quantitative proof for the reversibility of electro-elasto-mechanical deformations in piezoelectric crystals. For the following few decades, the piezoelectric property became a laboratory curiosity. Many more studies were done to discover crystal structures that exhibit piezoelectric properties. This resulted in the publication of Woldemar Voigt's Lehrbuch der Kristallphysik (textbook on crystal physics), which described in detail using tensor analysis the piezoelectric constants and 20 natural crystal classes with piezoelectric properties.

Signaling facilities are generally installed at intersections, entrances and exits of some link roads and pedestrian crossings that are not intersections. For pedestrian crossings that are far from intersections, a fixed-time signaling system can be implemented continuously or at certain times of the day in order to provide pedestrians with safe passage. On the other hand, in places where and at times when pedestrian flow is low, the continuous right-of-way given to vehicles is suspended when pedestrians press the relevant buttons.

Pedestrian alerts can also be used at intersections. These alerts can be a part of semi or fully actuated traffic signaling system and can also be useful in fixed-time intersections.

Particularly in some fixed-time intersections, in order to avoid loss of time and reduce delays, some pedestrian crossing alerts continuously signal red light unless there is any demand from pedestrians. Pedestrians that want to use such crossings have to press the relevant buttons and wait to get right-of-way.

IP Code stands for “international protection code” or “ingress protection code”. As can be understood from its complete form, IP protection class is an international standard developed by the European Commission (CENELEC—Comité Européen de Normalization Electrotechnique) to determine the resistance of electrical appliances against the external factors. IP code should be given to electrical appliances to specify safe working conditions.

IP rating is a 2- or 3-digit number; since the 3^{rd} digit is not included in IEC 60529, it is mostly not used. In order to easily express the resistance against different effects, each digit in the IP rating indicates protection against a separate effect and the numbers therein indicate the degree of protection.

Meanings of the digits used in IP Classification:
1. Protection from solids
2. Protection from liquids

Piezos used in the present technique have a short life and are not durable in conditions such as flood and rain and in cases of bad weather, and cannot show an efficient endurance for a long time in all kinds of weather conditions. Accordingly, in cases where lighting is insufficient, various traffic accidents may occur.

With respect to the piezos used in the present technique, it is known that the pressure only affects the point where it is applied and around thereof. When it comes to long lengths such as pedestrian crossings, this does not activate the piezos on the side close to the opposite side and sometimes the pressure cannot be transmitted as a signal, thus causing inefficiency.

Pedestrian buttons used at the present signalized intersections and especially those developed for disabled pedestrians are buttons in a diameter of a few cm mounted on signalized poles. It is practically impossible for a visually impaired pedestrian to find this button in the signalized intersection. Although an audible warning is used by the pedestrian button, such a warning may be insufficient to guide due to the noise of vehicles passing through and the presence of different sounds in external environment. In cases where such buttons are contactless, these problems will continue and particularly, the difficulty for visually impaired pedestrians to find the button will increase.

For other pedestrians and particularly for hearing impaired pedestrians, the signal is provided via point light sources on the present pedestrian buttons. In this case, the information indicating whether the pedestrian button is pressed or not cannot be noticed due to other pedestrians therearound.

Pedestrians have to touch pedestrian buttons to cross the street even during an epidemic. This causes further spread of diseases such as COVID-19 which is transmitted by contact. This is one of the downsides of pedestrian buttons. Therefore, there is a need for an invention to overcome these problems.

The invention described in patent application no. ES1070174 “Piezoelectric Device of Lighting of Zebra Steps With Optional Meter of Transfer of Vehicles” in the prior art comprises of a mechanism that transforms the pressure exerted by the footfall of the pedestrian into an electric current via piezoelectric crystals. The invention describes a mechanism activating the corresponding light source upon reception of a certain signal located on the right and left sides of the pedestrian crossing. In the patent application, it is described, with respect to piezoelectric crystals, that polymer composite materials are preferred due to being durable against the external environment such as differences in humidity and temperature and more preferably, materials such as polyvinyl chloride are used. In the document, piezo crystals are used as an energy source and the light source installed on the ground is radiated with the energy generated by the pressure applied on these crystals.

Another invention described in patent application no. WO2020041710A1 “DYNAMIC PAVER DEVICE WITH VIBRATION FEEDBACK” in the prior art is summarized as follows: “A paver device comprising a paver having a top surface and a bottom surface; a paver frame; at least one pressure sensor, wherein the at least one pressure sensor detects a change in an amount of pressure applied to the top surface of the paver; a vibration system connected to the bottom surface of the paver, wherein the vibration system is configured to provide a vibrational force to the bottom surface of the paver; and a controller connected to the at least one pressure sensor and the vibration system, and configured to; receive, from the at least one pressure sensor, a presence indication of an object on the top surface of the paver based on the detected change in the amount of pressure being applied to the top surface; and, in response to receiving the presence indication, transmit a signal to the vibration system to provide the vibrational force.” However, despite the generation of energy via pressure, no signalization system is described therein.

Another invention described in patent application no. CN105386416A “Intelligent Zebra Crossing” in the prior art is specified with a principle claim as follows, thereby describing the induction lighting method of a pedestrian bridge: “A pedestrian bridge induction lighting method, wherein the pedestrian bridge consists of a main bridge and the main bridge has escalators at its both ends. The method described herein consists of the following steps: Installation of lamps on the pedestrian bridge and of pressure sensors on each step of the escalator; real-time determination of whether each pressure sensor detects pressure data, and repeating the step and lighting the lamp by detection thereof.” In this document, the pedestrian bridge consists of a main bridge and the main bridge has escalators at its both ends; the method includes installation of lamps on the pedestrian bridge and of pressure sensors on each step of the escalator; real-time determination of whether each pressure sensor detects pressure data, and in cases where it is not detected, repeating the step. Induction lighting method for pedestrian crossing can turn on lighting on demand and has strong applicability. In this document, lamps installed in the zebra crossing alert passing by vehicles. In other words, a signaling program for traffic signal controller is not discussed in the document. It is mentioned therein that pedestrians apply a pressure on the zebra crossing while crossing the street.

### Definition of the Invention

The present invention aims to overcome above-mentioned disadvantages and to provide relevant technical field with new advantages and relates to a product controlled by waterproof piezo crystals that is developed to control, through such piezo crystals, signaling system triggered before, during and after pedestrians crossing at the signaled traffic intersections available for crosswalks; wherein the product is highly durable, long-lasting, and activates the signaling system without the need to press any button by detecting the pedestrians, thereby eliminating the risk of disease transmission.

Aim of this invention is to provide, in areas where it is used, a long-lasting and durable application by placing the crystals and electrical connections of the product in a flexible, waterproof and dustproof housing, which is rated at least IP68 according to IEC/EN 60529 standard.

Another aim of this invention is to ensure that the housing is made up of a composite material containing plastic derivatives and fiberglass reinforced polyester.

Another aim of this invention is to ensure that it does not deform at temperatures between −40° C. and +60° C. and does not lose its elasticity thanks to the chemical materials used.

Another aim of this invention is to ensure that it does not affected from sunlight and is resistant to ultraviolet rays and there is no discoloration thanks to the housing structure of the product, and that these advantages are provided by the ultraviolet resistant inverters placed in the raw material.

Another aim of this invention is to ensure that a tensile plate is positioned on piezo crystals used in the signaling system in order to distribute the pressure applied over the entire surface.

In the present invention, there is no need to search for a pedestrian button. In fact, visually impaired pedestrians are guided and directed by specifically textured tiles developed and laid on the ground especially for them and also, it is sufficient for them to step on the product with textured structure that is on the ground and to apply pressure thereon in order to create a demand without the need to press any button.

The invention also ensures that thanks to the lighting that is large enough and radiates from ground, whether or not a demand is created can be recognized easily and clearly by the visually impaired and other pedestrians. Moreover, pedestrians standing with their heads pointing towards the ground due to the great interest in smartphones nowadays can easily recognize the signal by lighting from the ground.

Another aim of this invention is to provide a lighting mechanism that enables hearing impaired pedestrians to perceive and recognize the signaling.

Another aim of this invention is to ensure that the product used in signaling system can also be mounted under the pavement.

Another aim of this invention is to ensure that no manual contact is required to create a demand on the product and accordingly, to prevent the spread of epidemic diseases such as COVID-19 via contact surface, thereby protecting human health.

### DRAWINGS

The applications of the present invention that is briefly summarized above and addressed in detail below can be understood by referring to the sample applications depicted in the attached drawings of the invention. However, it must be stated that the attached drawings show only the typical applications of this invention and that since the invention allows other equally effective applications, its scope cannot be assumed to be limited.

FIG. 1: An exploited view of the invention.

FIG. 2: A detailed view of the inventive parts piezo crystal, smart outer surface, led lighting material surfaces.

FIG. 3: A detailed view of the inventive parts tensile plate, polyester gel, outer body material surfaces.

In order to facilitate understanding, identical reference numbers are used to indicate identical elements in the figures, where possible. The shapes are not drawn to scale and can be simplified for clarity. It is believed that the elements and features of an application can be usefully incorporated into other applications without further explanation.

### EXPLANATION OF DETAILS IN DRAWINGS

The reference numbers shown in the figures are explained below.
1. Piezo crystal
2. Smart outer surface
3. Led lighting
4. Tensile plate
5. Polyester gel
6. Outer body

### DETAILED EXPLANATION OF THE INVENTION

Alternatives preferred for this detailed description of the product configuration controlled with waterproof piezo crystals of the invention are described only to ensure a better understanding of the subject and in a way that will not create any limiting impact.

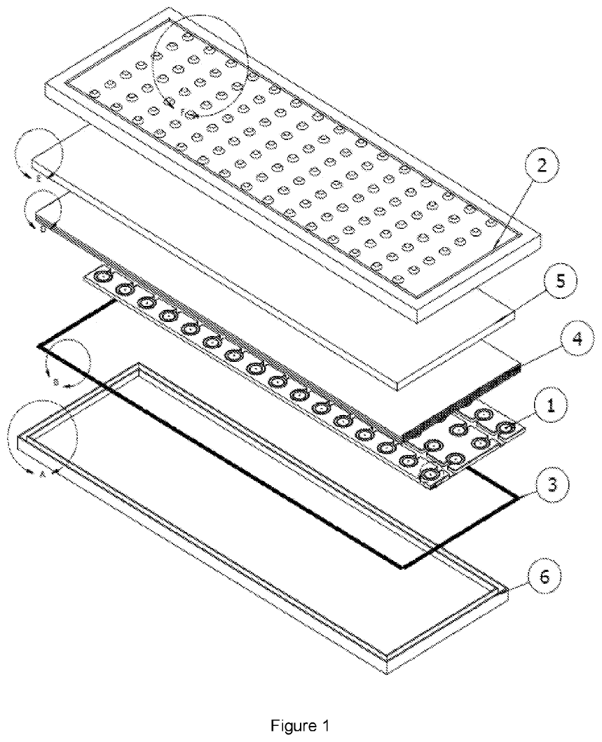

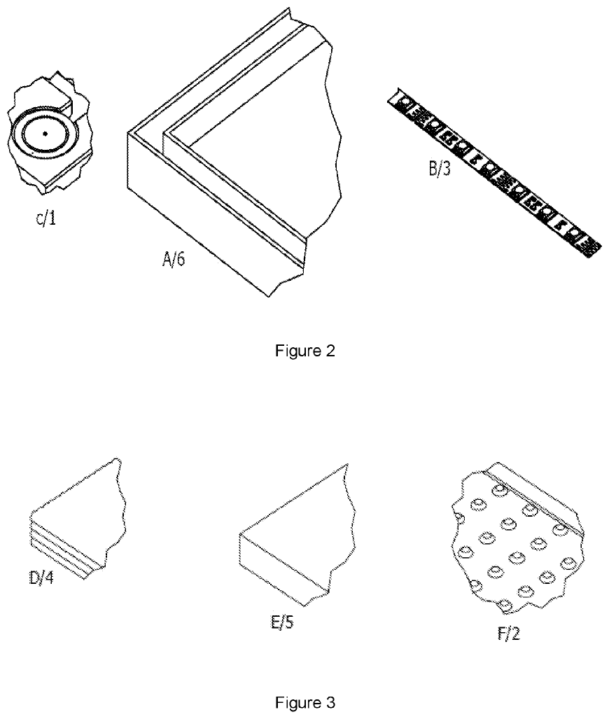

The invention is a product controlled with waterproof piezo crystals, wherein the product comprising of piezo crystal (1), smart outer surface (2), led lighting (3), tensile plate (4), polyester gel (5) and outer body (6) as shown in FIGS. 1, 2 and 3.

As shown in FIGS. 1, 2 and 3, the invention is characterized by comprising of a piezo crystal (1) that produces electrical voltage when pressure difference is created thereon, and a smart outer surface (2) with protrusions for visually impaired pedestrians that is produced from a material containing fiberglass reinforced polyester, which prevents water or dust from penetrating the lower surfaces, and a led lighting (3) installed under the smart outer surface (2) or on the outer body (6) that provides illumination over the ground, and a tensile plate (4) that, thanks to its conductive nature, evenly distributes and transfers to other piezo crystals (1) the force transmitted on itself when pedestrians step and apply pressure anywhere on the smart outer surface (2), and a polyester gel (5) that protects not only the smart outer surface (2) but also the internal structure against water and dust, and an outer body (6) at the bottom of the invention that is produced from a material containing fiberglass reinforced polyester which protects the internal structure from water and dust.

Piezo crystal (1) has the ability to generate electrical voltage if and when pressure difference occurs on the material. With the piezo material placed in the invention, this voltage is used to detect the presence of a pedestrian.

When pressed on the product installed on ground, that is, when pressure applied thereon, an electrical signal is generated. The force applied on the product is transmitted equally to all parts thereof by means of the tensile plate (4) mounted thereinside and the pressure is distributed over the entire surface. Therefore, it is sufficient to press anywhere on the product to generate electrical signal. A liquid material can be used, instead of tensile plate (4), to distribute the pressure over the entire surface. However, in this case, the liquid to be used will have to be placed in a housing that will prevent it from leaking. Thus, it should be prevented that the liquid decreases over time by evaporation depending on the temperature. Also, freezing point of the liquid to be used must be below −40° C. Preferably, the material to be used to produce the tensile plate (4) of the invention is steel for being able to transmit the force directly.

The generated electrical signal is transmitted to an electronic card. The electronic card sends this information to a traffic signal controller. Based on this information, the traffic signal controller ensures that the traffic signal lights are properly lit through a signaling program that has been previously installed therein. The electronic card system and traffic signal controller are not included in the scope of this patent. An electronic card appropriate for the traffic signal controller to be used will be designed. Therefore, design of the electronic card may vary.

It is enough for the pedestrian who wants to cross to just step on the smart outer surface (2) on the ground, without the need to press any button, to generate electrical energy and activate the signaling system. The fact that there is no need to touch any surface prevents the spread of epidemic diseases, as well as providing a serious advantage for disabled individuals.

Pressure sensors or piezo crystals (1) in the product are stored in a waterproof dustproof outer body. In addition to the smart outer surface (2) and the outer body (6), the piezo sensors are also protected from water and dust using polyester gel (5) chemical material. The polyester gel (5) will be able to transmit the pressure applied on the product to piezo crystals (1) or pressure sensors and will be resistant to outdoor conditions despite being inside of the smart outer surface (2).

External structure of the invention consists of a lower cover and an upper cover. The upper cover is referred to herein as smart outer surface (2) and the lower cover as outer body (6). The strip led lighting (3) is installed in the spaces on the outer body (6). The strip led lighting (3) structure can be installed on the outer body (6) or under the smart outer surface (2) in a way to glow from the parts with protrusions for visually impaired individuals. In this case, a transparent surface will be placed between the smart outer surface (2) and the led lighting (3), thereby leaving the necessary space for light output from the parts with protrusions for visually impaired individuals. As described herein, the outer body (6) and the smart outer surface (2) comprise of a composite material containing fiberglass reinforced polyester, which makes them waterproof and dustproof. This material structure will transmit the pressure difference created by the pedestrians to the internal sensors and will be able to fully fulfill its duty for at least two years under outdoor conditions. The smart outer surface (2) and outer body (6) connections, which form the outer structure of the invention, will be connected to each other in a way that prevents water and dust penetrating thereinside. Waterproof and dustproof seals will be used for this connection.

The crystals and electrical connections of the invention will be placed in a waterproof and dustproof housing that is rated at least IP68 according to the IEC/EN 60529 standard. Furthermore, the housing material will also be flexible enough to allow sufficient pressure difference to be transmitted to the crystals. To this end, a composite material containing plastic derivatives or fiberglass will be used for the smart outer surface (2) and outer body (6) of the invention.

There are standardized reliefs on the smart outer surface (2) for visually impaired pedestrians. With the product, demand of the visually impaired pedestrian to cross is received through the floor on which the pedestrian directly steps without searching and using any button at the intersection. When the pedestrians step on the smart outer surface (2), receipt of their request is announced via the audio announcement system. Thereafter, when the signal light turns to green, pedestrians are informed by the audio announcement system about the fact that they can now cross the street. Similarly, when the signal light turns to red, it will be announced that they must wait.

On the product, there is also a visual-lighting guide for the hearing impaired pedestrians. The lighting guide, which is off when there is no demand on the product, is activated and glows red when someone steps on the product, i.e. the smart outer surface (2). In this way, receipt of the demand can be visually recognized. Once the lamps have turned red, there is no need to keep standing on the product. The red light will stay on until the green light turns on. When the signaling lamp turns green for pedestrians, the guide lamps will also glow green and remain as such during the time the signaling lamp is green. After the signaling lamp turns red and if and when there is no new demand on the product, the lighting guide will no longer glow.

Lamps inside the lighting guide are accessible independently of the section in which sensors are housed. Thus, if and when these lamps break down or a maintenance is required, they can be easily repaired and/or replaced. However, the piezo crystals (1) inside the polyester gel (5) will not require maintenance and fulfill their duty for at least two years.

Sensor cables and feeder cables for led lighting (3) will emerge from under the outer body (6) structure. The cables to be used will be NYY or TTR type cables that are heavy duty and resistant to outdoor conditions.

The product will be mounted next to the signaling pole in a way such that it is at the same level with the tiles placed for visually impaired pedestrians. In addition, if and when specifically requested, the product can be mounted underground in a way such that it cannot be seen from the outside.

The smart outer surface (2) and outer body (6) of the invention will be flexible enough to transmit the pressure difference to piezo crystals (1). To this end, a composite material containing plastic derivatives or fiberglass will be used for the smart outer surface (2) and outer body (6). Moreover, the section where piezo crystals (1) or connections thereof are located will be housed within a chemical material. Thus, they will be completely isolated from the external environment and the outer layers that surround them. This also provides a secondary protection for the crystals and connections therebetween. The chemical material to be used for this purpose should not be affected by pressure differences, should not degrade between the temperatures of −40° C. and +60° C. and should not lose its elasticity. The smart outer surface (2) and outer body (6), which are called the housing structure of the invention, will not be affected by sunlight and will be resistant to ultraviolet rays. During the warranty period for the product, there will be no discoloration due to sunlight. This will be provided by the inverters resistant to ultraviolet rays that are placed in the raw material used for the housing structure.

The piezo crystals (1) in the invention will be connected to each other in series and in parallel to provide sufficient current and voltage values. Depending on the desired sensitivity levels, sensitivity level of the electronic card used, length of the cable used and distance of the invention from ground (and depth of embedding if it will be embedded in the ground), the desired voltage values will differ. To this end, two or more piezo crystals (1) should be connected in series to provide the required voltage values. For a potential error in series connection, a connection in parallel is required in order for the invention to continue operating. As a result thereof, there must be at least one connection in series and at least one connection in parallel within the invention. However, if a single piezo crystal (1) structure provides the desired voltage value, there is no need for a connection in parallel. This is because the electronic card must be triggered for the signaling system to be activated. Therefore, these connection types are needed.

Led lighting (3) will be off when there is no pedestrian demand and it will glow in the color of the current pedestrian signal when a pressure-induced demand is created. For example, if and when the pedestrian signal is red, the lamps on the product will also be red. With the signal turning green, the lamps thereon will also turn red. When specifically requested, the lamps on the product can be configured in a way such that they flash with the first demand.

In alternative configurations of the invention, a different pressure-triggered material can be used instead of piezo crystals (1). Moreover, for these types of configurations, alternative products that can generate electrical energy following pressure can be used in the product instead of piezo crystals (1).

1- The invention relates to a product controlled with waterproof piezo crystals developed to control, through piezo crystals, the signaling system triggered before, during and after the crossing by pedestrians at signaled traffic intersections, wherein the product is highly durable and long-lasting, and activates the signaling system, without the need to press any button, by detecting the pedestrians, thereby eliminating the risk of disease transmission; characterized in that it comprises of:
a piezo crystal (1) that produces electrical voltage when pressure difference is created thereon,
a smart outer surface (2) with protrusions for visually impaired pedestrians that is produced from a material containing fiberglass reinforced polyester, which prevents water or dust from penetrating the lower surfaces,
a led lighting (3) installed under the smart outer surface (2) or on the outer body (6) that provides illumination over the ground,
a tensile plate (4) that, thanks to its conductive nature, evenly distributes and transfers to other piezo crystals (1) the force transmitted on itself when pedestrians step and apply pressure anywhere on the smart outer surface (2),
a polyester gel (5) that protects not only the smart outer surface (2) but also the internal structure against water and dust,
an outer body (6) at the bottom of the invention that is produced from a material containing fiberglass reinforced polyester which protects the internal structure from water and dust.

2- A product controlled with waterproof piezo crystals according to claim 1, wherein the smart outer surface (2) and outer body (6) are made up of a composite material containing fiberglass reinforced polyester or plastic and derivatives thereof.

3- A product controlled with waterproof piezo crystals according to claim 1, characterized in that the product consists of a smart outer surface (2) and an outer body that are not affected by sunlight and resistant to ultraviolet rays because of the ultraviolet-resistant inverters placed therein.
